(19) United States
(12) Patent Application Publication
(10) Pub. No.: US 2010/0007355 A1
(43) Pub. Date: Jan. 14, 2010

(54) METHOD FOR TESTING RADIO FREQUENCY (RF) RECEIVER TO PROVIDE POWER CORRECTION DATA

(75) Inventors: Christian Volf Olgaard, Sunnyvale, CA (US); Carsten Andersen, Sunnyvale, CA (US); Peter Petersen, Brentwood, CA (US); Wassim El-Hassan, Koebenhavn N (DK)

Correspondence Address: VEDDER PRICE P.C., 222 N. LASALLE STREET, CHICAGO, IL, 60601, US

(73) Assignee: LitePoint Corporation, Sunnyvale, CA (US)

(21) Appl. No.: 12/170,677

(22) Filed: Jul. 10, 2008

(51) Int. Cl. G01R 35/00; G01R 27/32

(52) U.S. Cl. 324/601; 324/629

(57) ABSTRACT

A method for testing a radio frequency (RF) receiver as a device under test (DUT) with one or more test instruments to provide a plurality of relative power correction factors, a plurality of received signal strength indication (RSSI) calibration factors, or both.

### BACKGROUND

1. Field of Invention

The present invention relates to testing of radio frequency (RF) receivers, and in particular, to testing RF receivers to perform faster power measurements and calibrations.

2. Related Art

Most RF receivers, including wireless RF receivers, use an input filter, generally a band pass filter, to provide frequency band selectivity. This filter attenuates out-of-band signals that otherwise would be received and processed within the receiver, and thereby use receiver resources for undesired signals, and potentially prevent proper processing of the desired in-band signals. These filters typically have high quality factors (high Q) with relatively steep roll-off, i.e., frequency attenuation versus frequency, outside the desired frequency range. However, as is well known in the art, such high Q filters typically have attenuation ripple throughout the frequency pass band. Such ripple can often be as much as one decibel (dB) or more across the desired frequency band.

Referring to FIG. 1, a typical frequency response for such a filter is represented by two response curves 1, 2. The upper response curve 1 shows the attenuation with reference to the left vertical axis, while the lower curve 2 is a “zoomed in” view of the upper curve 1 but with reference to the right vertical axis. Such variation affects operation of the receiver since signals received at difference frequencies will have different receive path losses between the input (e.g., antenna) and the baseband signal processor. Accordingly, it is often required that calibration of the system be done to ensure that the received power is constant over the frequency band of interest. This is particularly important in digital signal systems that use power control and support multiple users simultaneously. In such systems, the received power must be accurately reported for the system to work reliably.

Traditionally, this type of calibration involves providing a known signal to the receiver front end and measuring the received power at a given frequency. For example, a known power level will be transmitted from a signal source (e.g., a test instrument) in the form of a continuous wave (CW) signal or a packet-based signal. The received signal will be analyzed for power, and a gain offset factor will be applied and stored in the system so that the power at that frequency can be reported correctly in the future. Advantageously, particularly with modem digital receivers, such power calculations can be performed inside the device under test (DUT), thereby allowing the DUT to perform the desired calibration compensation without further interaction with the test instrument, rather than changing the input frequency. Hence, test time is generally limited by control of the test instrument so as to ensure that the input signal power (as provided by the test instrument) is stable and at the correct frequency, e.g., by allowing sufficient time for settling in terms of signal power and frequency.

Alternatively, in a time division duplexed (TDD) system, compensation for the filter ripple can be calibrated by transmitting power out of the transmitter of the DUT and measuring such transmitted power. In a frequency division duplexed (FDD) system, such as a cellular telephone system, it will generally be necessary to perform calibration for both transmit and receive functions.

In addition to calibration of the band select filter, which can generally be done at a single power level, it is often desirable to calibrate the received signal strength indication (RSSI) operation. This will also involve the band select filter calibration, since it will be necessary to compensate the loss variation introduced by the band select filter, while also calibrating the receiver gain linearity to ensure that the reported RSSI is correct over both frequency (due to the band select filter ripple) and the input power level. Generally, implementation is similar to that described above where a known power is provided by a reference source (e.g., a test instrument) and the DUT will generate a correction factor based on the known input power level. As before, since most receive measurements can be performed inside the DUT, the test time for this type of calibration is also generally limited by the speed of the test equipment.

In conventional test techniques, a signal generator is used to provide a signal at a known power level to the DUT, one frequency at a time. While this is generally done since it replicates normal system operation, it is also based on traditional RF test equipment architecture. For fast test times, such instrumentation must be able to change frequency quickly, which involves a trade-off between settling time and system phase noise performance. Generally, phase noise performance is improved at the expense of settling time. In modern digital communication systems, for example, with high modulation accuracy requirements, this can be problematic and require more costly test equipment.

### SUMMARY

In accordance with the presently claimed invention, a method is provided for testing a radio frequency (RF) receiver as a device under test (DUT) with one or more test instruments to provide a plurality of relative power correction factors, a plurality of received signal strength indication (RSSI) calibration factors, or both.

In accordance with one embodiment of the presently claimed invention, a method for testing a radio frequency (RF) receiver as a device under test (DUT) with one or more test instruments to provide a plurality of relative power correction factors includes:

transmitting, with the one or more test instruments, a broadband signal containing a plurality of sub-carrier signals each of which has a respective one of one or more predetermined power levels and is centered about a respective one of a plurality of frequencies;

receiving the broadband signal with the DUT;

selecting respective ones of the plurality of sub-carrier signals;

measuring a power level for each of the selected respective ones of the plurality of sub-carrier signals to provide a corresponding one of a plurality of power level measurements;

comparing each of the plurality of power level measurements with a corresponding one of the one or more predetermined power levels to provide a corresponding one of the plurality of relative power correction factors; and

storing the plurality of relative power correction factors for use by the DUT.

In accordance with another embodiment of the presently claimed invention, a method for testing a radio frequency (RF) receiver as a device under test (DUT) with one or more test instruments to provide a plurality of received signal strength indication (RSSI) calibration factors includes:

transmitting, with the one or more test instruments, a broadband signal containing a plurality of sub-carrier signals each of which has a respective one of a plurality of predetermined power levels and is centered about a respective one of a plurality of frequencies;

receiving the broadband signal with the DUT;

selecting respective ones of the plurality of sub-carrier signals;

measuring a power level for each of the selected respective ones of the plurality of sub-carrier signals to provide a corresponding one of a plurality of power level measurements;

comparing each of the plurality of power level measurements with a corresponding one of the plurality of predetermined power levels to provide a corresponding one of the plurality of RSSI calibration factors; and

storing the plurality of RSSI calibration factors for use by the DUT.

In accordance with another embodiment of the presently claimed invention, a method for testing a radio frequency (RF) receiver as a device under test (DUT) with one or more test instruments to provide a plurality of relative power correction factors and a plurality of received signal strength indication (RSSI) calibration factors includes:

transmitting, with the one or more test instruments, a broadband signal containing a plurality of sub-carrier signals each of which has a respective one of a plurality of predetermined power levels and is centered about a respective one of a plurality of frequencies;

receiving the broadband signal with the DUT;

selecting respective ones of the plurality of sub-carrier signals;

measuring a power level for each of the selected respective ones of the plurality of sub-carrier signals to provide a corresponding one of a plurality of power level measurements;

comparing each of the plurality of power level measurements with a corresponding one of the one or more predetermined power levels to provide a corresponding one of the plurality of relative power correction factors and a corresponding one of the plurality of RSSI calibration factors; and

storing the pluralities of relative power correction factors and RSSI calibration factors for use by the DUT.

### BRIEF DESCRIPTION OF THE DRAWINGS

FIG. 1 is a graph of an exemplary frequency response of a surface acoustic wave (SAW) filter.

FIG. 2 is a functional block diagram of a test implementation in accordance with an exemplary embodiment of the presently claimed invention.

FIG. 3 is a functional block diagram of a typical device under test (DUT) for testing in accordance with an exemplary embodiment of the presently claimed invention.

FIGS. 4-8 illustrate various input signal spectrums for testing a DUT in accordance with exemplary embodiments of the presently claimed invention.

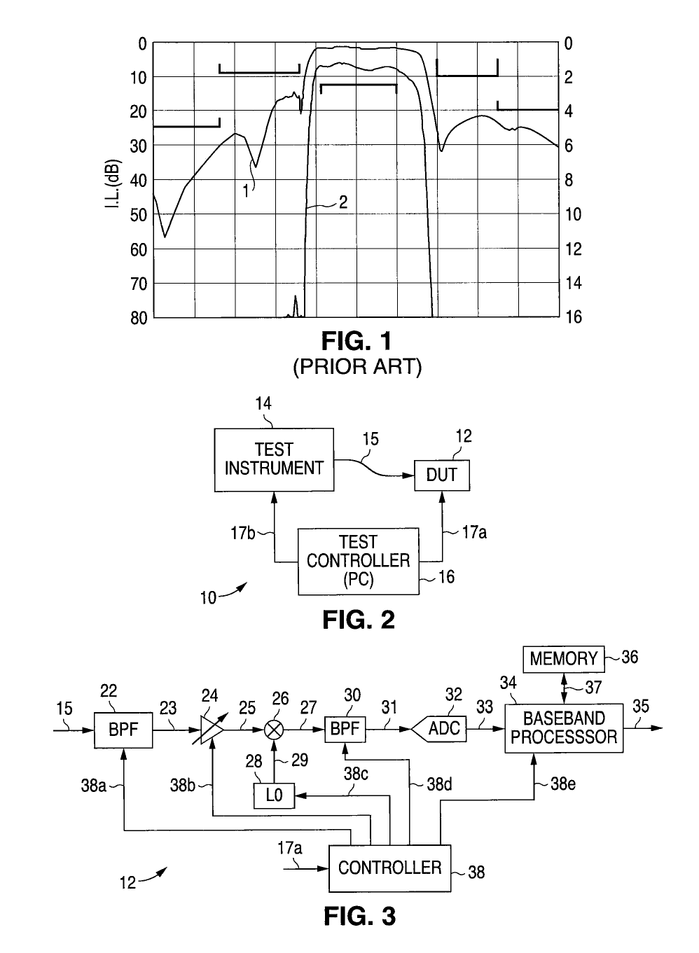

### DETAILED DESCRIPTION

The following detailed description is of example embodiments of the presently claimed invention with references to the accompanying drawings. Such description is intended to be illustrative and not limiting with respect to the scope of the present invention. Such embodiments are described in sufficient detail to enable one of ordinary skill in the art to practice the subject invention, and it will be understood that other embodiments may be practiced with some variations without departing from the spirit or scope of the subject invention.

Throughout the present disclosure, absent a clear indication to the contrary from the context, it will be understood that individual circuit elements as described may be singular or plural in number. For example, the terms “circuit” and “circuitry” may include either a single component or a plurality of components, which are either active and/or passive and are connected or otherwise coupled together (e.g., as one or more integrated circuit chips) to provide the described function. Additionally, the term “signal” may refer to one or more currents, one or more voltages, or a data signal. Within the drawings, like or related elements will have like or related alpha, numeric or alphanumeric designators. Further, while the present invention has been discussed in the context of implementations using discrete electronic circuitry (preferably in the form of one or more integrated circuit chips), the functions of any part of such circuitry may alternatively be implemented using one or more appropriately programmed processors, depending upon the signal frequencies or data rates to be processed.

In accordance with the presently claimed invention, the sophistication levels of modern digital-to-analog converters (DACs) and vector signal generators (VSGs) can be advantageously used to implement test signals with large baseband bandwidths, as well as wide RF modulation bandwidths. Accordingly, frequency changes can be implemented at baseband rather than at RF as in a traditional RF synthesizer. Since such bandwidth is wider than necessary for testing, it is possible to operate the test equipment at a single fixed RF frequency and change the generated frequency by changing the generated baseband frequency. This allows for faster frequency changes in terms of testing within the DUT.

Additionally, such wide baseband bandwidth allows multiple-tone baseband signals to be generated. Accordingly, a broadband signal with multiple tones at specific frequencies can be generated. Further, it is possible to control the individual power levels of these tones. As a result, it is possible to generate a broadband signal that offers power at all desired channels (tones) simultaneously within a given frequency band. If all tones have the same power level, it is no longer necessary to provide synchronization between the DUT and the test instrument, since it is possible to merely have the DUT change its selected input frequency to the desired channel, measure the received power and, following confirmation of a valid power measurement, continue with another desired frequency selection. Hence, test and calibration time is now limited only the by the DUT and no longer by the test instrument.

Referring to FIG. 2, a test and calibration implementation 10 in accordance with an exemplary embodiment of the presently claimed invention includes the DUT 12, one or more test instruments 14 and a test controller (e.g., a personal computer) 16. The DUT 12 will receive the test signal 15 from the test instrument 14 under the control of one or more control signals 17a from the test controller 16, which also provides one or more control signals 17b to the test instrument 14. While the DUT 12 is generally a wireless device, i.e., receives its signals wirelessly during normal operation, the test signal 15 from the test instrument is preferably wired, i.e., via a cable, during testing to ensure reception of the test signal at a known power level. The control signals 17a for the DUT 12 are also generally wired, e.g., via universal serial bus (USB) or universal asynchronous receiver transmitter (UART). Similarly, the control signals 17b for the test instrument 14 are also generally wired, e.g., via USB, Ethernet or general purpose interface bus (GPIB).

Referring to FIG. 3, in accordance with an exemplary embodiment of the presently claimed invention, the DUT 12 typically includes an input band pass filter 22 which performs the frequency band selection operation, a variable gain amplifier 24, a mixer 26 and local oscillator 28 for performing frequency down conversion, another band pass filter 30 for intermediate frequency (IF) filtering, an ADC 32 and a baseband signal processor 34. (As will be readily appreciated, many current systems use quadrature signals I, Q which are demodulated by the mixer 26 and local oscillator 28 which using in-phase and quadrature-phase LO signals 29, in which cases the second filter 30 will be for the baseband quadrature signals I, Q and may include some gain control which, at this point in the received signal path, will have little impact on the overall receiver noise figure.) A controller 38 receives the one or more control signals 17a from the controller 16, and provides appropriate control signals 38a, 38b, 38c, 38d, 38e as needed for the band select filter 22, amplifier 24, local oscillator 28, IF/baseband filter 30 (with which sub-carrier selection is performed in accordance with one or more control signals 38d) and baseband signal processor 34. Additionally, memory 36 is included for communicating, via an interface 37, the compensation and calibration factors generated as part of the DUT testing.

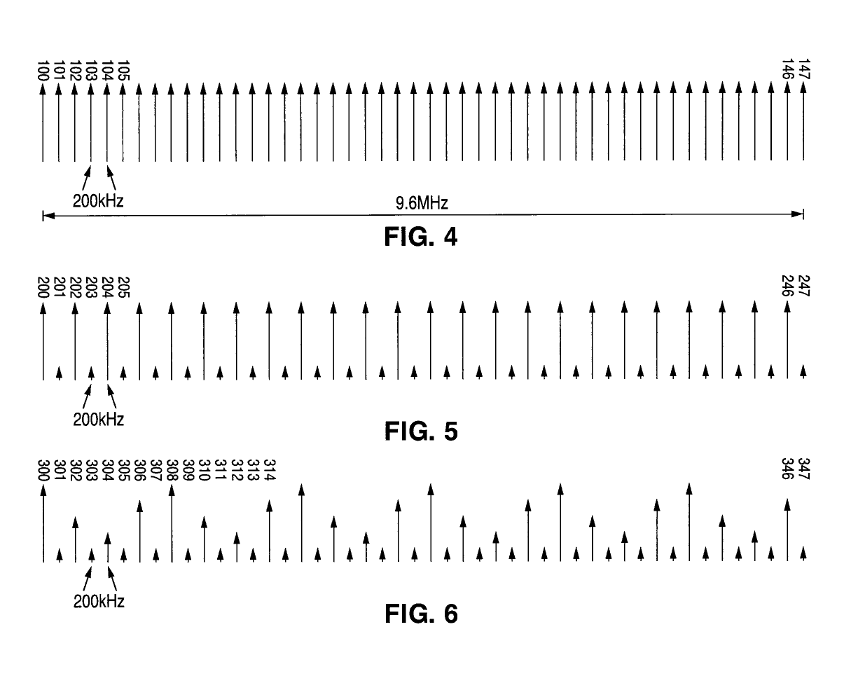

Referring to FIG. 4, in accordance with an exemplary embodiment of the presently claimed invention, the test instrument 14 (FIG. 2) provides its broadband signal 15 using orthogonal frequency divisional multiplexing (OFDM) modulation to provide multiple tones (or sub-carriers) 100, 101, 102, . . . , 147 with a predetermined frequency spacing. For purposes of this discussion, the test signal 15 is a GSM (Global System for Mobile) signal, although it will be readily appreciated that other types of signals can be used in accordance with the presently claimed invention. Accordingly, the channel spacing, i.e., frequency difference between the tones, is 200 kilohertz (kHz), thereby producing a 200 kHz raster. Each sub-carrier 100, 101, 102, . . . , 147 has the same power level and each pair of adjacent tones has the same 200 kHz frequency spacing, with the broadband signal 15 spanning 9.6 megahertz (MHz). The modulation of the individual sub-carriers 100, 101, 102, . . . , 147 can be simple CW modulation or, if desired, modulated in conformance with a GSM packet definition, as well as a combination of both. As discussed above, the DUT 12 has the ability to select any of the sub-carriers 100, 101, 102, . . . , 147 with its band select filter 22 (FIG. 3) and measure the corresponding sub-carrier signal power. Hence, since all sub-carriers 100, 101, 102, . . . , 147 are available simultaneously for selection and measurement, minimal, if any, synchronization is needed between the test instrument 14 and the DUT 16. A small program or sequence of instructions can be executed within the DUT 12 (e.g., within the controller 38) to select a desired sub-carrier, measure its power, and then continue with another sub-carrier to measure its power, and so on. Knowing the power of each transmitted sub-carrier 100, 101, 102, . . . , 147 enables the DUT 12 to compute the appropriate gain offset, or correction, to have the DUT 12 report the correct power at any measured sub-carrier frequency. It will be readily appreciated that for those sub-carriers not selected for measurement, appropriate gain compensation factors can be extrapolated based on those that are measured in accordance with well known techniques.

If it is desired to calibrate power over multiple power levels, the DUT 12 communicates to the test controller 16 when it has completed its measurements at the current power level and is ready to measure at a new power level. The controller 16 instructs the test instrument 14 to change the power level of its test signal 15, following which the controller 16 will instruct the DUT 12 to begin measurements at the new power level. Alternatively, the test instrument 14 can change the power level of its test signal 15 after a predetermined time of transmitting at the current power level. The DUT 12, aware of this time interval, will complete its power measurements and wait for the end of the time interval before beginning measurements at the expected new power level, allowing time as appropriate for the power to settle.

With all test sub-carriers 100, 101, 102, . . . , 147 transmitted at equal power levels, channel selectivity as provided by the band select filter 22 might be of concern under some circumstances. Using the GSM specification for purposes of this discussion, reference interference levels are +9 dB for co-channel interference, −9 dB for immediately adjacent (200 kHz) channel interference, −41 dB for next adjacent (400 kHz) channel interference, and so on. Accordingly, the receiver will be capable of attenuating a signal one channel away (200 kHz) by 18 dB (+9 dB−(−9 dB)=18 dB). Hence, even with all tones 100, 101, 102, . . . , 147 at the same power level, the power of the immediately adjacent channel will contribute only minimal extra power (e.g., approximately 0.07 dB for one adjacent tone, or 0.14 dB when accounting for adjacent tones on both sides). Such additional power, therefore, can generally be disregarded as insignificant, particularly since the receiver will often provide channel selectivity in excess of the specified minimum. At channels further away, the suppression is even better (e.g., 50 dB and more), so virtually no change in power should be detectable. Further, if CW tones are used, additional attenuation should be expected (since power spreading across frequency which occurs with modulation is not present and, although relatively narrow band, cannot be easily filtered), thereby improving accuracy still further.

Referring to FIG. 4, if adjacent channel influence remains a concern, modulation of the test signal 15 using OFDM can be modified to reduce the power of adjacent channels. As readily understood by one or ordinary skill in the art, individual sub-carriers in an OFDM signal can be controlled such that the power of every other sub-carrier is reduced, thereby ensuring attenuation of 50 dB or more of the closest sub-carrier by the receiver, and even greater attenuation for the remaining sub-carriers. With this type of modulation in the example as shown, the even sub-carriers 200, 202, 204, . . . , 246 retain the maximum power level, while the odd sub-carriers 201, 203, 205, . . . , 247 are attenuated significantly, thereby ensuring virtually no effect on the measured power of the even sub-carriers 200, 202, 204, . . . , 246 by the power of the odd sub-carriers 201, 203, 205, . . . , 247.

While it may be possible to remove virtually all power at the odd sub-carriers 201, 203, 205, . . . , 247, it is possible that some power will nonetheless be introduced, e.g., from quantization errors as part of the digital signal processing, or potentially from intermodulation between sub-carriers and IQ mismatches in the IQ modulator. While disabling every other sub-carrier should prevent direct intermodulation products from being introduced from the attenuated sub-carriers, some higher order intermodulation products may still be introduced. Alternatively, the broadband signal 15 can be generated such that the sub-carriers are spaced further apart, e.g., by 400 kHz rather than the 200 kHz prescribed by the GSM standard.

Referring to FIG. 5, it is often desirable to also calibrate RSSI over multiple input power levels. With a conventional test technique, it would be necessary to provide synchronization among the DUT 12 and test instrument 14 when changing the power level of the test signal 15. However, in accordance with an exemplary embodiment of the presently claimed invention, the test signal 15 includes tones with different power levels. For example, the odd sub-carriers 301, 303, 305, . . . , 347 can be attenuated, while the even sub-carriers 300, 302, 304, . . . , 347 retain higher, but varied, power levels. For example, sub-carriers 300, 308 and so on can have a first power level (e.g., the highest), sub-carriers 302, 310 and so on can have a second power level, sub-carriers 304, 312 and so on can have a third power level, and sub-carriers 306, 314 and so on can have a fourth power level. The DUT 12 can perform its power calibration for a given power level by measuring the corresponding sub-carriers having a particular power level. In this example, this will allow power measurements for sub-carriers separated by 1.6 MHz (8*200 kHz), which can still allow sufficient resolution of this gain variation measurement. By performing this calibration for each set of corresponding sub-carriers, the DUT 12 can complete its measurements and calibrations without requiring synchronization or communication with the test instrument 14 as would otherwise be necessary before changing the power level of its test signal 15 for subsequent measurements.

Referring to FIG. 7, it is not necessary to attenuate all odd sub-carriers, and a more optimal distribution of power may include repeated sequences of declining power levels across the frequency test band. In this example, one out of every seven sub-carriers is not used, e.g., sub-carriers 406, 413 and so on have virtually no power. If the power variations between adjacent sub-carriers are 5 dB and the receiver can attenuate adjacent frequencies by 18 dB (as discussed above), this results in a minimum of 13 dB attenuation of the signal to the left of the sub-carrier being tested, and 23 dB attenuation of the signal to the right. The worst case error introduced by these levels is approximately 0.23 dB. For many RSSI calibration requirements, this is satisfactory, since the accuracy of the RSSI reporting is often within 2 dB. Further, the receiver will often perform better than the specified minimum performance, particularly with CW sub-carriers. Further still, for the highest power sub-carriers (400, 407, 414 and so on) the error introduced by power from an adjacent sub-carrier is only 0.02 dB since the sub-carrier to the left has virtually no power and the sub-carrier to the right is already 5 dB lower in power. This allows spanning of a 30 dB power range over only seven sub-carriers. Of course, other power distributions can be used as desired.

As noted above, intermodulation and IQ mismatches can limit the possible dynamic range of the test instrument 14, and, therefore, the dynamic range that a signal test signal 15 can produce. If a larger dynamic range is desired, changing power of the test signal 15 during a test may be necessary. While it is possible to have the test synchronized before and after such power change, an alternative approach is to use a predetermined time and power relationship.

Referring to FIG. 8 for example, the test instrument 14 can transmit its test signal 15 using a sub-carrier distribution similar to that of FIG. 7 but with a first peak power level 500 during a first time interval T1-T2, followed by a time interval T2-T3 during which the test instrument 14 changes the peak power of its test signal 15 from the first peak power level 500 to a lower peak power level 510. As of time T3, this peak power level 510 will have settled and testing of the DUT 12 can begin. During the first time interval T1-T2, the DUT 12 will measure the powers of the respective sub-carriers (as discussed above), following which it will wait until time T3 to begin testing again at the lower peak power level 510. (Power levels 520 and 530 indicate those power levels during their respective time intervals T1-T2, T3-T4 where accurate power measurement may be difficult due to intermodulation, noise or IQ mismatches in the test instrument 14.) With this type of measurement scenario, the only synchronization between the DUT 12 and test instrument 14 which may be required will be knowledge on the part of the DUT 12 when testing is to first begin at time T1, following which the DUT 12 can keep track of time to ensure timely completion of testing prior to time T2, followed by resumption of testing at time T3 and completion of testing at time T4, while avoiding testing during time interval T2-T3.

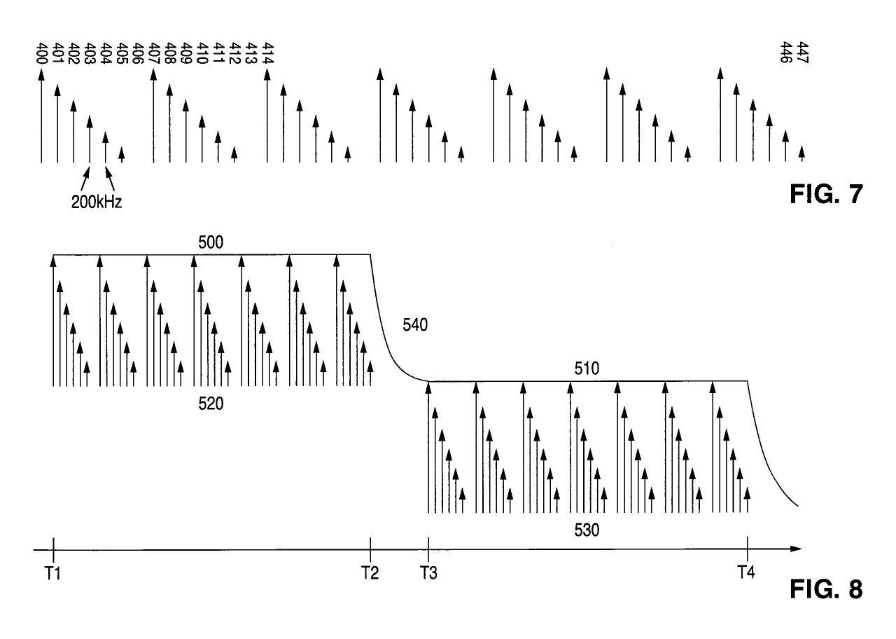

While CW sub-carriers are represented in the examples discussed above, (FIGS. 4-8), it will be readily appreciated that each sub-carrier can contain modulation in the form of data packets as required by the DUT 12 to measure power in accordance with its normal operation. As is well know, using a VSG provides for the generating of complex signals and, since the signals for test purposes will generally be static, generating of the test signal need not occur in real time, but can be generated earlier, stored in memory and simply played back from memory when needed.

Various other modifications and alternations in the structure and method of operation of this invention will be apparent to those skilled in the art without departing from the scope and the spirit of the invention. Although the invention has been described in connection with specific preferred embodiments, it should be understood that the invention as claimed should not be unduly limited to such specific embodiments. It is intended that the following claims define the scope of the present invention and that structures and methods within the scope of these claims and their equivalents be covered thereby.

What is claimed is:

1. A method for testing a radio frequency (RF) receiver as a device under test (DUT) with one or more test instruments to provide a plurality of relative power correction factors, comprising:
transmitting, with said one or more test instruments, a broadband signal containing a plurality of sub-carrier signals each of which has a respective one of one or more predetermined power levels and is centered about a respective one of a plurality of frequencies;
receiving said broadband signal with said DUT;
selecting respective ones of said plurality of sub-carrier signals;
measuring a power level for each of said selected respective ones of said plurality of sub-carrier signals to provide a corresponding one of a plurality of power level measurements;
comparing each of said plurality of power level measurements with a corresponding one of said one or more predetermined power levels to provide a corresponding one of said plurality of relative power correction factors; and
storing said plurality of relative power correction factors for use by said DUT.

2. The method of claim 1, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals having substantially mutually equal power levels.

3. The method of claim 1, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals mutually adjacent ones of which have mutually unequal power levels.

4. The method of claim 1, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals mutually adjacent portions of which have respective pluralities of mutually unequal power levels.

5. The method of claim 1, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals with mutually adjacent portions each of which includes a sub-plurality of sub-carrier signals having a maximum power level, a minimum power level, and one or more power levels intermediate and between said maximum and minimum power levels.

6. The method of claim 1, wherein said transmitting, with said one or more test instruments, a broadband signal containing a plurality of sub-carrier signals each of which has a respective one of one or more predetermined power levels and is centered about a respective one of a plurality of frequencies comprises transmitting, with said one or more test instruments, a broadband signal containing a plurality of sub-carrier signals mutually adjacent ones of which are separated by substantially equal frequency differences.

7. A method for testing a radio frequency (RF) receiver as a device under test (DUT) with one or more test instruments to provide a plurality of received signal strength indication (RSSI) calibration factors, comprising:
transmitting, with said one or more test instruments, a broadband signal containing a plurality of sub-carrier signals each of which has a respective one of a plurality of predetermined power levels and is centered about a respective one of a plurality of frequencies;
receiving said broadband signal with said DUT;
selecting respective ones of said plurality of sub-carrier signals;
measuring a power level for each of said selected respective ones of said plurality of sub-carrier signals to provide a corresponding one of a plurality of power level measurements;
comparing each of said plurality of power level measurements with a corresponding one of said plurality of predetermined power levels to provide a corresponding one of said plurality of RSSI calibration factors; and
storing said plurality of RSSI calibration factors for use by said DUT.

8. The method of claim 7, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals mutually adjacent ones of which have mutually unequal power levels.

9. The method of claim 7, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals mutually adjacent portions of which have respective pluralities of mutually unequal power levels.

10. The method of claim 7, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals with mutually adjacent portions each of which includes a sub-plurality of sub-carrier signals having a maximum power level, a minimum power level, and one or more power levels intermediate and between said maximum and minimum power levels.

11. The method of claim 7, wherein said transmitting, with said one or more test instruments, a broadband signal containing a plurality of sub-carrier signals each of which has a respective one of one or more predetermined power levels and is centered about a respective one of a plurality of frequencies comprises transmitting, with said one or more test instruments, a broadband signal containing a plurality of sub-carrier signals mutually adjacent ones of which are separated by substantially equal frequency differences.

12. A method for testing a radio frequency (RF) receiver as a device under test (DUT) with one or more test instruments to provide a plurality of relative power correction factors and a plurality of received signal strength indication (RSSI) calibration factors, comprising:
transmitting, with said one or more test instruments, a broadband signal containing a plurality of sub-carrier signals each of which has a respective one of a plurality of predetermined power levels and is centered about a respective one of a plurality of frequencies;
receiving said broadband signal with said DUT;
selecting respective ones of said plurality of sub-carrier signals;
measuring a power level for each of said selected respective ones of said plurality of sub-carrier signals to provide a corresponding one of a plurality of power level measurements;
comparing each of said plurality of power level measurements with a corresponding one of said one or more predetermined power levels to provide a corresponding one of said plurality of relative power correction factors and a corresponding one of said plurality of RSSI calibration factors; and
storing said pluralities of relative power correction factors and RSSI calibration factors for use by said DUT.

13. The method of claim 12, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing first and second sub-pluralities of sub-carrier signals, wherein each of said first sub-plurality of sub-carrier signals has a respective power level substantially equal to a first power level, each of said second sub-plurality of sub-carrier signals has a respective power level substantially equal to a second power level, and said first and second power levels are unequal.

14. The method of claim 12, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals mutually adjacent ones of which have mutually unequal power levels.

15. The method of claim 12, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals mutually adjacent portions of which have respective pluralities of mutually unequal power levels.

16. The method of claim 12, wherein said transmitting, with said one or more test instruments, a broadband signal containing a plurality of sub-carrier signals each of which has a respective one of one or more predetermined power levels and is centered about a respective one of a plurality of frequencies comprises transmitting a broadband signal containing a plurality of sub-carrier signals with mutually adjacent portions each of which includes a sub-plurality of sub-carrier signals having a maximum power level, a minimum power level, and one or more power levels intermediate and between said maximum and minimum power levels.

17. The method of claim 12, wherein said transmitting, with said one or more test instruments, a broadband signal containing a plurality of sub-carrier signals each of which has a respective one of one or more predetermined power levels and is centered about a respective one of a plurality of frequencies comprises transmitting, with said one or more test instruments, a broadband signal containing a plurality of sub-carrier signals mutually adjacent ones of which are separated by substantially equal frequency differences.
